(19) United States
(12) Patent Application Publication
(10) Pub. No.: US 2008/0222473 A1
(43) Pub. Date: Sep. 11, 2008

(54) TEST PATTERN GENERATING DEVICE AND TEST PATTERN GENERATING METHOD

(75) Inventor: Kazuhiro TAKU, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, KAWASAKI (JP)

(21) Appl. No.: 12/014,119

(22) Filed: Jan. 15, 2008

(30) Foreign Application Priority Data
Mar. 9, 2007 (JP) 2007-60536

(51) Int. Cl. G06F 11/263; G01R 31/28; G06F 11/25

(52) U.S. Cl. 714/738; 714/E11.177; 714/E11.155

(57) ABSTRACT

An apparatus for LSI test has a risk place extraction unit supplied with a design information of the LSI to specify a place by estimating an error in LSI operation based on the design information of the LSI to write the place on a risk place list, and a pattern generator unit coupled to the risk extraction unit to generate a test pattern responsive to the risk place list, wherein the pattern generator unit generates the test pattern with an operation of the LSI being controlled to be lower than a predetermined threshold to prevent the error in LSI operation from occurring.

### FIELD OF THE INVENTION

The present invention relates to a LSI circuit test technology and specifically to a test pattern generating technology for scan testing LSI.

### BACKGROUND OF THE INVENTION

In order to scan test a LSI, it is necessary to generate a scan test pattern (hereinafter referred to simply as “test pattern”). Lately, high-compression test patterns are generated for the purpose of reducing the number of test patterns or the testing time.

However, higher the compression rate of a test pattern is, higher the toggle rate within a LSI tends to be. Consequently, at the time of logic test, an error occurs in the operation of the test scan chain due to an IR drop of the power source (hereinafter referred to simply as “IR drop”), and as a result of the test, good products may be determined as out-of-specification items leading to a fall in yield.

JP-A No. 2006-66825 discloses a test-pattern generating technology that takes into account IR drop and layout, and FIG. 18 corresponding to FIG. 1 in JP-A No. 2006-66825 shows a LSI test design supporting device that applies this technology.

In the LSI test design support device shown in FIG. 18, the RC network analysis unit 4 analyses the physical form of the wiring used for supplying power voltage, the distance from the power source, and the power source system, and outputs the RC network analysis result 5. Based on the RC network analysis result 5 and the IR drop analysis result mentioned below 9, a scan circuit grouping unit 6 groups scan flip-flops that can perform scan test operations at the same time and outputs scan circuit group information 7. Based on the scan circuit group information 7, the IR drop analysis unit 8 wherein scan flip-flops of a same group start operating all at once analyzes whether an IR drop occurs for each group and acquires an IR drop analysis result 9. An IR drop analysis result determination unit 10 compares the IR drop analysis result 9 and the determination value 18 and determines whether errors occur in the operation of scan flip-flops due to the IR drop.

When it is determined that errors occur in their operation, the scan circuit grouping unit 6 regroups scan flip-flops, and the IR drop analysis unit 8 and the IR drop analysis result determination unit 10 process them for each group obtained by the regrouping. These regroupings, analyses of IR drop, and the determination of IR drop analyses result are repeated until the moment when errors do not occur in the operation of each group.

When the IR drop analysis result determination unit 10 determines that errors in operation do not occur, a scan chain insertion unit 11 changes the scan chain of the logics connection information 1 based on the scan circuit group information 7 of that time. This change in scan chain is realized by controlling the scan mode or the clock. Test patterns are generated for the changed scan chains so that a plurality of scan chains may not operate at the same time.

In other words, this technology includes the step of constituting the scan chain so that errors in the operation of the scan chain due to an IR drop may be avoided at the time of scan test, and the step of generating test pattern based on the scan chain that has been constructed.

However, the technology described in the JP-A No. 2006-66825 tries to avoid errors in LSI operation due to an IR drop by changing the construction of the scan chain and making a new layout. This brings about a problem in that the TAT (turn-around time) required for the completion of the layout increases.

And in the case of changing the scan chain by using a clock control circuit, it is necessary to repeat the whole work beginning with the CTS (clock tree synthesis) on the layout, leading to a sharp increase in the TAT for the completion of the layout.

And at the time of generating test patterns, due to the presence of chains that are not operated for the purpose of avoiding errors in LSI operation due to an IR drop, the pattern length and testing time of the test pattern increases.

The solution of these problems while trying to avoid errors in LSI operation due to an IR drop constitutes an important problem in the realization of efficient scan tests.

Incidentally, the generation of a test pattern for which the toggle rate in the LSI is reduced is a possible solution. However, the effect of an IR drop of the power source is related with the layout of the LSI, and the generation of a test pattern in such a way that the toggle rate may be simply reduced without taking into account the layout limits the substantive effect of avoiding errors in the LSI operation.

### SUMMARY

In accordance with the present invention, there is disclosed an apparatus having a risk place extraction unit and a pattern generator unit, that substantially eliminate disadvantages of prior art.

An apparatus for LSI test has a risk place extraction unit supplied with a design information of the LSI to specify a place by estimating an error in LSI operation based on the design information of the LSI to write the place on a risk place list, and a pattern generator unit coupled to the risk extraction unit to generate a test pattern responsive to the risk place list.

Incidentally, a method, a system or a program resulting from replacing the apparatus is effective as an aspect of the present invention.

### BRIEF DESCRIPTION OF THE DRAWINGS

FIG. 1 is an illustration showing the test pattern generation device according to the first embodiment of the present invention;

FIG. 2 is an illustration showing an example of division of a chip by the IR drop calculation unit in the test pattern generation unit shown in FIG. 1;

FIG. 3 is an illustration showing examples of IR drop values calculated by the IR drop calculation unit for each of the blocks shown in FIG. 2;

FIG. 4 is an illustration of risk places estimated by the risk place estimation unit in FIG. 1 by using the example shown in FIG. 3;

FIG. 5 is an illustration showing an example of the risk place list corresponding to the example of FIG. 4;

FIG. 6 is a flowchart showing the flow of processing by the risk place extraction unit in the test pattern generation device shown in FIG. 1;

FIG. 7 is a flowchart showing the flow of processing of the pattern generator unit in the test pattern generation device shown in FIG. 1;

FIG. 8 is an illustration showing the test pattern generation device according to the second embodiment of the present invention;

FIG. 9 is a flowchart showing the flow of processing of the risk place extraction unit in the test pattern generation device shown in FIG. 8 (No. 1);

FIG. 10 is a flowchart showing the flow of processing of the risk place extraction unit in the test pattern generation device shown in FIG. 8 (No. 2);

FIG. 11 is an illustration showing an example of risk place list outputted by the risk place estimation unit in the test pattern generation device shown in FIG. 8 (No. 1);

FIG. 12 is an illustration showing an example of risk place list outputted by the risk place estimation unit in the test pattern generation device shown in FIG. 8 (No. 2);

FIG. 13 is an illustration showing the test pattern generation device according to the third embodiment of the present invention;

FIG. 14 is a block diagram showing the flow of processing of the risk place estimation unit in the test pattern generation device shown in FIG. 13;

FIGS. 15A, 15B, 15C, and 15D are an illustration for describing a specific example of processing by the risk place estimation unit in the test pattern generation device shown in FIG. 13;

FIG. 16 is an illustration showing the test pattern generation device according to the fourth embodiment of the present invention;

FIG. 17 is an illustration showing the test pattern generation device according to the fifth embodiment of the present invention; and

FIG. 18 is an illustration showing an example of the prior art.

### DESCRIPTION OF THE PREFERRED EMBODIMENT

We will describe below the embodiments of the present invention with reference to drawings.

### First Embodiment

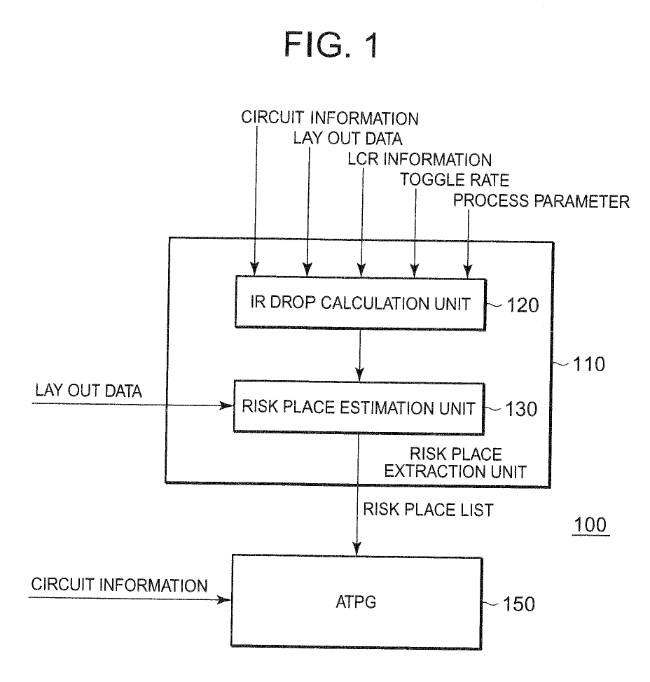

FIG. 1 shows a test pattern generation device 100 related to the first embodiment of the present invention. The test pattern generation device 100 is for generating test patterns used in scan testing LSI chips (hereinafter referred simply as “chips”), and includes a risk place extraction unit 110 for extracting risk places where errors in LSI may occur during a test due to an IR drop in the power source, and a pattern generator unit 150 for generating test patterns in such a way that the constraint may be applied to the toggle rate of the instances included in the risk places extracted by the risk place extraction unit 110. In the following descriptions, the pattern generator unit 150 shall be referred to as ATPG (Automatic Test Pattern Generator) 150.

Incidentally, the chips to be processed by the test pattern generation device 100 of this embodiment are chips whose layout (the layout of the user circuit and the layout of the scan chain) has been completed, and the risk place extraction unit 110 extracts risk places by using the layout data, toggle rate, circuit information (net list, clock information, frequency information, power consumption of various functional elements in the chip), process parameters, the LCP (coil, capacitance, and resistance) information of the package (hereinafter referred to as “PKG”) of these chips.

The toggle rate of the chips whose layout has been completed mentioned here means a toggle rate for which the normal operation of these chips is assumed when they are implemented on actual devices. Therefore, naturally these chips do not cause errors in LSI operation due to an IR drop in the power source at this toggle rate or noises and the like, because the circuit and the layout are designed in anticipation of normal operation when they are implemented in actual devices so that no errors occur in LSI.

We would like to add for a supplementary information the situation anticipated in the present application as a problem is errors in LSI operation that occur when these chips are subjected to a logic test in particular to a scan test at a value in excess of the toggle rate assumed at the time of design. On the other hand, it is possible that circuits and layout may be designed based on the assumption of an excessive toggle rate during a scan test at the time of design. This means however imparting an excessive quality, and must be avoided in order to avoid a cost increase.

As FIG. 1 shows, the risk place extraction unit 110 includes an IR drop calculation unit 120 and a risk place estimation unit 130.

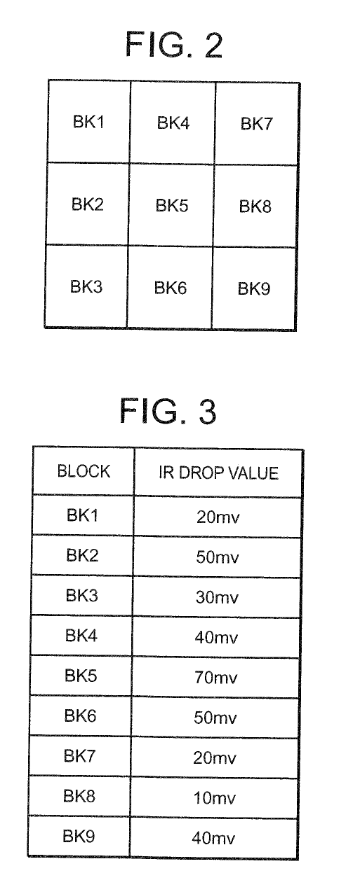

The IR drop calculation unit 120 divides in the first place the chip in a plurality of mesh blocks of an equal area. FIG. 2 shows an example of division into small blocks by the IR drop calculation unit 120. According to the case illustrated, the number of blocks is 3×3=9. However, this is variable depending on the magnitude and construction of the chip, and is not limited to the illustrated example.

The IR drop calculation unit 120 calculates the IR drop value for each block shown in FIG. 2. The IR drop value may be calculated by various traditional methods. For example, static IR drop value may be calculated from the RC network information (contained in the layout data) of the power source wiring and the toggle rate of the chip, the LCR information of the PKG, process parameters, and the power consumption of the functional elements contained in the block (contained in the circuit information). Or dynamic IR drop values may be calculated by extracting noises from the frequency information of various elements in the block.

The toggle rate of a chip means a plurality of data for each of the blocks constituting the chip and for each of the instances constituting the block, and may adopt the structure of storing the plurality of toggle rates as input information.

FIG. 3 shows an example of IR drop calculated for each of the blocks shown in FIG. 2. The IR drop calculation unit 120 outputs the results of calculation shown in FIG. 3 to the risk place estimation unit 130.

Based on the result of calculation as shown in FIG. 3 obtained by the IR drop calculation unit 120, the risk place estimation unit 130 recognizes risk places where errors in LSI may occur during a test due to a IR drop of the power source. Specifically, it compares the IR drop value of the block and the predetermined reference value, and recognizes the blocks having an IR drop value larger than the reference value as risk places.

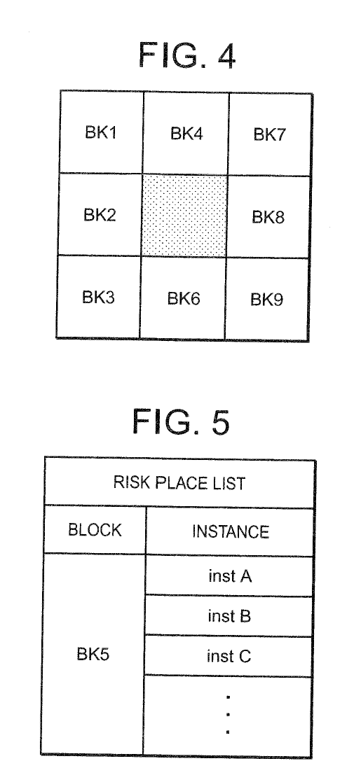

Here, the term “reference value” means a threshold value for determining whether there is a possibility of errors occurring in LSI operation during a test or not, and it is variable depending on the magnitude and the construction of the chip. Here, we take a value of “60 mv” as an example. Accordingly, as a result of comparison with the reference value of 60 mv, the IR drop value (70 mv) of the block BK 5 is larger than the reference value, the risk place estimation unit 140 determines the block BK5 shown in FIG. 4 (black block in the figure) as a risk place.

The risk place estimation unit 130 generates a risk place list covering the information for identifying the blocks determined as risk places (for example block identification number, here BK5) and the instance information showing the instances included in the blocks and outputs the same to the ATPG150. Incidentally, the risk place estimating unit 130 acquires the instance information of the blocks to be specified as risk places by referring the layout data.

FIG. 5 shows an example of the risk place list outputted by the risk place estimation unit 130. As illustrated, the risk place list outputted by the risk place estimation unit 130 lists up the identification information (BK5) of the blocks determined as risk places and each of the instances (instA, instB, instc, . . . being correlated each other.

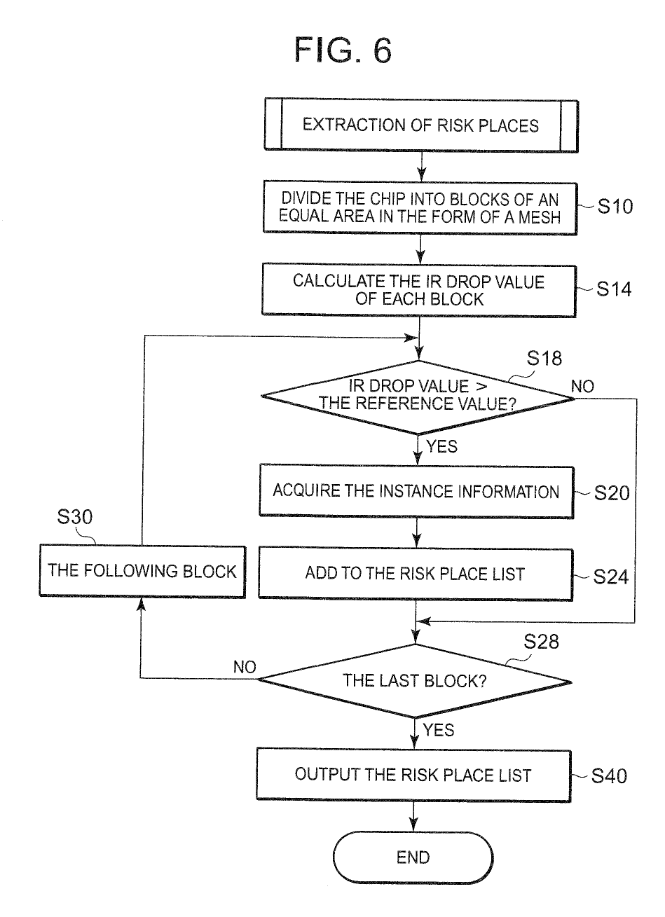

FIG. 6 is a flowchart showing the flow of processing steps in the risk place extraction unit 110. As shown in the figure, for extracting risk places, the IR drop calculation unit 120 divides in the first place the chip into a plurality of blocks of an equal area in a mesh and calculates the IR drop value of each block (S10, S14). The risk place estimation unit 130 compares the IR drop value obtained from the IR drop calculation unit and the reference value, determines the blocks whose IR drop value is larger than the reference value as risk places, and refers the layout data and acquires the instance information contained in the blocks and adds them to the risk place list by associating them (S18: Yes, S24). On the other hand, it determines that the blocks whose IR drop value is equal to or less than the reference value as not risk places (S18: No). The risk place estimation unit 130 performs the operations described from the step S18 through the step 23 for each block (S28: No, S30, S18-S24), and after completing the processing of the last block (S28: Yes), outputs the risk place list to the ATPG150 to terminate the risk place extraction process (S40).

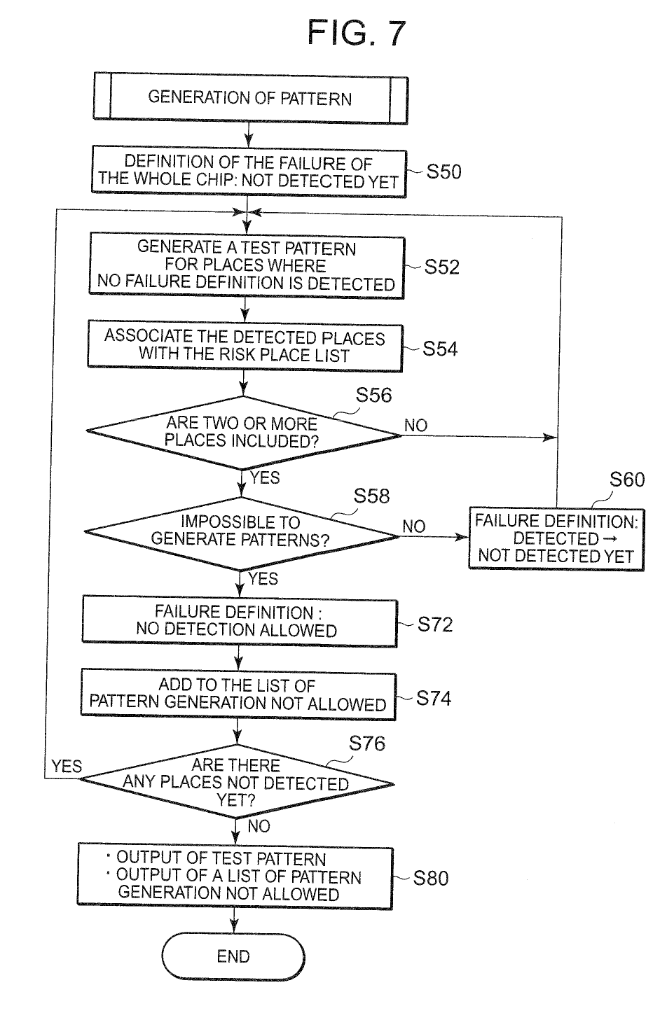

We will now describe below the operation of the ATPG150. The ATPG150 generates test patterns by using net lists contained in the circuit information and the risk place list outputted by the risk place extraction unit 110. FIG. 7 is a flowchart showing the flow of processing by the ATPG150.

As FIG. 7 shows, the ATPG150 defines in the first place failures for the whole chip based on the circuit information. The “definition of failure” means defining whether the nodes in the chip are in the “detected” state or “undetected” state, and normally this is done on all the nodes in a chip. In the following description, the nodes on which definition of failure has been completed are referred to as “failure-defined place.” And the term “detected” means the state in which it is possible to obtain the state of element corresponding to the place of failure definition (whether normally working or not) by applying a test pattern to the place of failure definition during a scan test, and the term “not detected yet” or “undetected” means the contrary of “detected,” and means a state in which it is not possible to obtain the state of element corresponding to the place of failure definition even if a test pattern is applied to the place of failure definition during a scan test.

Here, for default setting, the ATPG150 designates all the nodes in the chip as places of failure definition, and sets their state as “not detected yet.” Incidentally, the ATPG 150 associates each place of failure definition with its state, in other words in which state between “detected” and “not detected yet” the place of failure definition is and stores the same as a failure-definition file.

The ATPG150 generates test patterns for all the places of failure definition that have been defined as “not defined yet,” and renews the failure-definition file in such a way that the state of the places of failure definition that have been detected (hereinafter referred to as “place of detection”) as a result of the generation of the test pattern may shift from “not detected yet” to “detected” (S52).

And the ATPG150 associates the places of detection with the risk place list (S54). This association is a processing to determine whether there are places of detection in the respective block of the risk place list and to obtain their number if the answer is positive.

If the number of places for detection is one or less in a block, the processing of THE ATPG150 returns to the step S52, and starts processing other “undetected” places for failure detection beginning with the step S52 (S56: No. S52-). On the other hand, if there are two or more places for detection in a block, the ATPG150 further determines whether it is possible to generate further test patterns or not (S56: Yes, S58).

As the places for detection correspond to the operational instances, the number of places for detection also corresponds to the number of operational instances. When a block contains a plurality of operational instances, it sometimes becomes impossible to generate test patterns due to constraints that must be observed such as the requirement for operatively at the same time in view of the configuration of the circuit. In the step S58, the ATPG150 determines whether it is possible to generate test patterns or not, and in case of a determination that it is possible, the ATPG150 renews the failure definition file in such a way that the state of each place for detection with the block may shift from “detected” to “not detected yet”, and its process returns to the step S52 (S58: No. S60, S52 and subsequent steps). Incidentally, with regards to the fact that the state of these places for detection in the failure-detection file, following the generation of test patterns in the step S52, their state was switched to “for detection.”

On the other hand, when it is determined as impossible to generate in the step S58, the ATPG150 changes the state of the relevant places for detection in the failure-detection file from “detected” to “not allowed to detect” and renews the failure-detection file (S58: Yes, S72). And the ATPG150 adds to the list of pattern generation not allowed showing the places for failure definition that it has determined as “detection not allowed” (S74).

The processing described in step S52-step S57 are repeated until the moment when the places of failure definition in the “not detected yet” state disappear in the failure definition file (S76: Yes, S52 and subsequent steps). This will bring all the places for failure definition in the failure definition file into either the “detected” state or the “detection not allowed” state.

When the places for failure definition in the “undetected” state have disappeared in the failure definition file (S76: No), the ATPG150 terminates the procession by outputting test patterns and the list of pattern generation not allowed (S80).

In other words, when the blocks listed in the risk place list includes a plurality of operational instances, the ATPG150 generates test patterns in such a way that the constraint may be applied to the toggle rate of instances in the block by not allowing these instances to change at the same time.

Accordingly, the test pattern outputted by the test pattern generation device 100 does not cause errors in LSI to occur due to a IR drop during a test.

Thus, the test pattern generation device 100 according to the present embodiment divides a chip into a plurality of blocks and extracts the blocks in which errors in LSI operation occur due to an IR drop of the power source from among these blocks as risk places. When there are a plurality of operational instances in the blocks extracted as risk places, test patterns are generated in such a way that constraints may be applied to the toggle rate of these instances in order to prevent any errors in LSI operation from occurring due to an IR drop in the power source. In order to prevent the feedback to layout designs from occurring, it is possible to restrict TAT and perform efficient scan tests by applying the technology described in JP-A No. 2006-66825 of avoiding errors in LSI operation due to an IR drop by making a new layout of the scan chain.

Here, we will describe further in details test patterns for which the toggle rate is constrained. The lower limit of the constrained toggle rate is, as described above, the toggle rate during the normal operating time stored as the data base at the time of designing, and at this toggle rate no errors in LSI operation basically occurs due to an IR drop.

Against this lower limit of toggle rate, the toggle rate at which errors in LSI operation may occur due to an IR drop can be the upper limit. Therefore, an adequate test pattern is generated according to various conditions between this upper limit and the lower limit of toggle rate. Various conditions mentioned here correspond to variations described in the second embodiment to the fifth embodiment. And these various conditions are not limited to these embodiments and may be combined with changes, increase or decrease or other combinations.

And any correction made to the layout of the scan chain for test after the completion of the user circuit layout may sometimes affect the layout of the user circuit. The test pattern generation device 100 according to this embodiment does not change the layout of the scan chain and does not affect the layout of the user circuit.

The technology of the JP-A No. 2006-66825 has a problem in that the length of a test pattern and the test time increases because of the presence of scan chains that stop operation in order to avoid errors in LSI operation due to an IR drop. On the other hand, the test pattern generation device 100 of this embodiment can solve the problem of increases in the pattern length of the test pattern and the test time because all the chains can operate.

In addition, the technology of the JP-A No. 2006-66825, which involves changes in scan chains due to the control of the scan mode and the control of the clock, requires circuits for these controls, and therefore the circuit dimensions grow larger constituting another problem. On the other hand, the test pattern generation device 100 of this embodiment does not require the addition of these circuits and therefore can prevent the errors in LSI operation from occurring due to an IR drop without any increase in the size of circuits.

And because of the division of a chip into a plurality of blocks of an equal size, it is easy to calculate to identify the position of the block.

### Second Embodiment

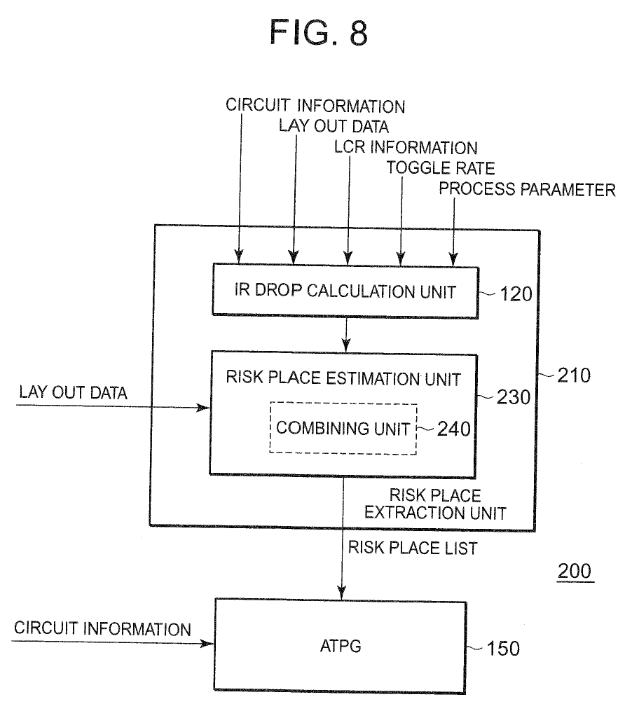

FIG. 8 shows the test pattern generation device 200 according to the second embodiment of the present invention. The test pattern generation device 200 is also an apparatus for generating test patterns for scan testing chips and includes a risk place extracting unit 110 for extracting risk places where errors in LSI operation can occur during a test due to an IR drop in the power source, and the ATPG150 for generating test patterns in such a way that a constraint may be applied to the toggle rate of the instances included in the risk places extracted by the risk place extraction unit 110. Here, in FIG. 8 we assigned the same codes to the units having the same configuration or function as those of the test pattern generation device 100 according to the first embodiment shown in FIG. 1 and we omit detailed description of the same.

The risk place extraction unit 210 of the test pattern generation device 200 according to the second embodiment shown in FIG. 8 is different from the risk place extraction unit 110 of the test pattern generation device 100. As shown in the figure, the risk place extraction unit 210 includes a IR drop calculation unit 120 and a risk place estimation unit 230, and the risk place estimation unit 230, unlike the risk place estimation unit 130 in the risk place extraction unit 110, includes a combination unit 240.

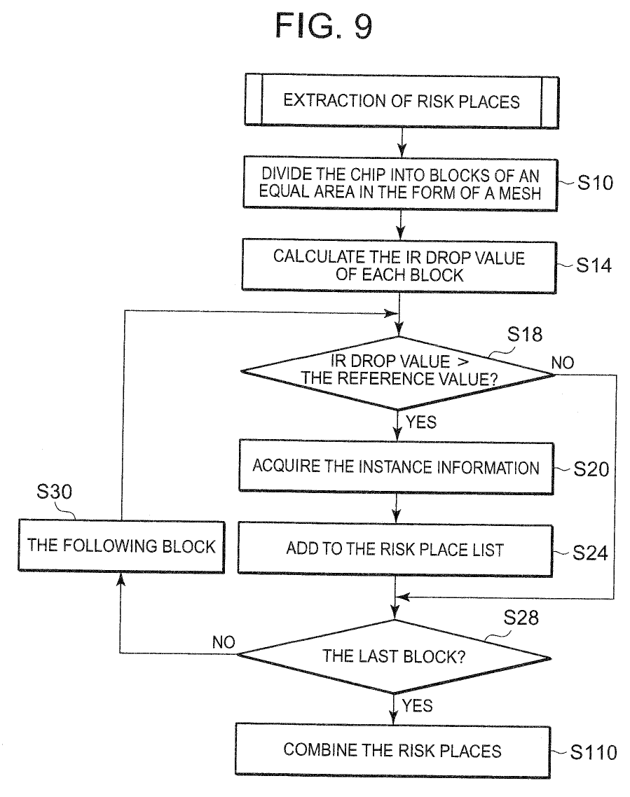

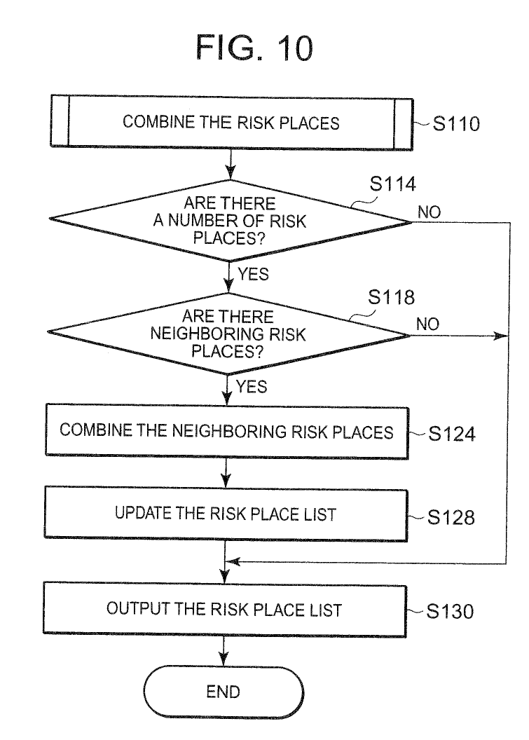

FIG. 9 and FIG. 10 are flowcharts showing the process executed by the risk place extraction unit 210. As FIG. 9 shows, for extracting risk places, the IR drop calculation unit 120 divides the chip into a plurality of blocks of an equal area in a mesh, and calculates the IR drop value of each block (S10, S14). The risk place estimation unit 230 compares the IR drop value of the block obtained by the IR drop calculation unit 120 with the reference value, determines the blocks whose IR drop value is larger than the reference value as risk places, refers the layout data and obtains the instance information in the blocks, and adds the same to the risk place list (S18: Yes, S24). On the other hand, it determines the blocks whose IR drop value is equal to or smaller than the reference value as not risk places (S18: No). The risk place estimation unit 230 executes the process from the step S18 through the step S24 on each block of the chip (S28: No. S30, S18-S24), and when the processing of the last block is completed (S28: Yes), the combination unit 240 performs the combination processing of blocks (S110).

In other words, the processing from the step S10 through the step S30 performed by the risk place extracting unit 210 is the same as the processing of the risk place extraction unit 110 performed by the risk place extraction unit 110. [Sic]

FIG. 10 is a flowchart showing the processing of combining the risk places performed by the combination unit 240. As the figure shows, the combination unit 240 refers in the first place the risk place list obtained by the processing ending with the step S30, and determines whether there are a plurality of blocks determined as risk places or not (S114). If the number of blocks determined as risk places is equal to or less than one, the risk place list is outputted as it is to the ATPG150 (S110: No. S130) On the other hand, if there are a plurality of blocks determined, as the combination unit 240 refers the layout data and determines whether there are any neighboring blocks or not among these plurality of blocks determined as risk places (S118).

If there is no neighboring blocks determined as risk places, the combination unit 240 outputs the risk place list as it is to the ATPG150 (S118: No, S130). On the other hand, if there are neighboring blocks determined as risk places, the combination unit 240 combines the neighboring blocks determined as risk places into a block and renews the risk place list (S118: Yes, S124, S128). For this combination, the combination unit specifically combines the neighboring risk-place blocks into a single block and assigns a new block number. At the same time, it associates each instance included in these risk places with the block to which a new block number has been assigned before renewing the risk place list. Upon the completion of the combination, the combination unit outputs the renewed risk place list to the ATPG150 and finishes the extraction of the risk places (S130).

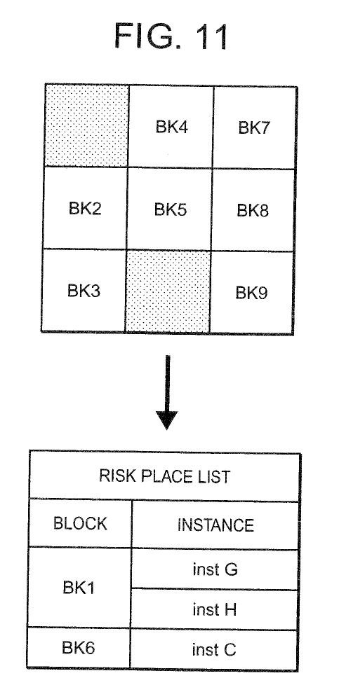

FIG. 11 shows an example of a risk place list outputted by the risk place extraction unit 210 when there are no neighboring blocks determined as risk places (S118: No). In the example shown in the figure, the block BK1 which includes the instances instG and instH and the block BK6 which includes the instance instC are extracted as the risk places of the chip. In this case, since BK1 and BK6 are not neighboring, the risk place list outputted by the risk place extraction unit 210 associates the instances included respectively in BK1 and BK6.

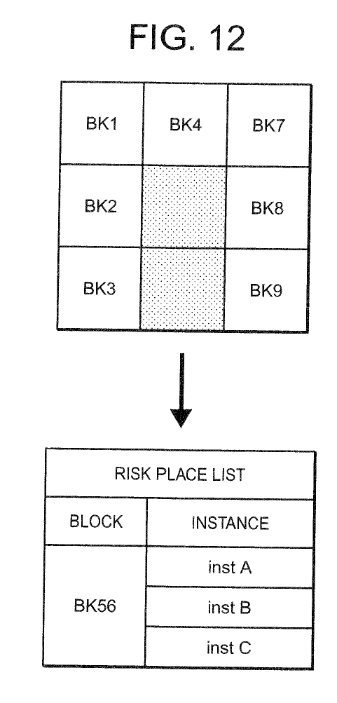

FIG. 12 shows an example of a risk place list outputted by the risk place extraction unit 210 when there are neighboring blocks determined as risk places (S118: Yes). In the example shown in the figure, the block BK5 which includes the instances instA and instB and the block BK6 which includes the instance instC are extracted as the risk places of the chip. In this case, since BK1 and BK6 are neighboring, the risk place list outputted by the risk place extraction unit 210 associates the instances included (instA, instb, instC) in BK56 representing the block resulting from the combination of the block BK5 and the block BK6.

The ATPG150 generates test patterns by using a net list included in the circuit information and a risk place list outputted by the risk place extraction unit 110. If the block number included in the risk place list is a combined block number, the combined block is considered as a block for the generation of test patterns. Since the generation of test patterns by the ATPG150 is similar to that of the ATPG150 in the test pattern generation device 100, we omit the detailed description thereof.

Functional elements operating at the same time on a chip sometimes stride over blocks, and when risk places are neighboring, even if a constrain is applied to the toggle rate for instance for each risk place, it is sometimes impossible to avoid effectively the occurrence of errors in LSI operation due to an IR drop. When blocks determined as risk places are neighboring, the test pattern generation device 200 according to this embodiment is designed to combine the neighboring blocks into a single block and to generate test patterns in such a way that a constrain may be applied to the toggle rate of instances in the combined block. As a result, it is possible to obtain the same effect as the test pattern generation device 100, and to avoid the effect of any IR drop with a higher degree of certainty.

### Third Embodiment

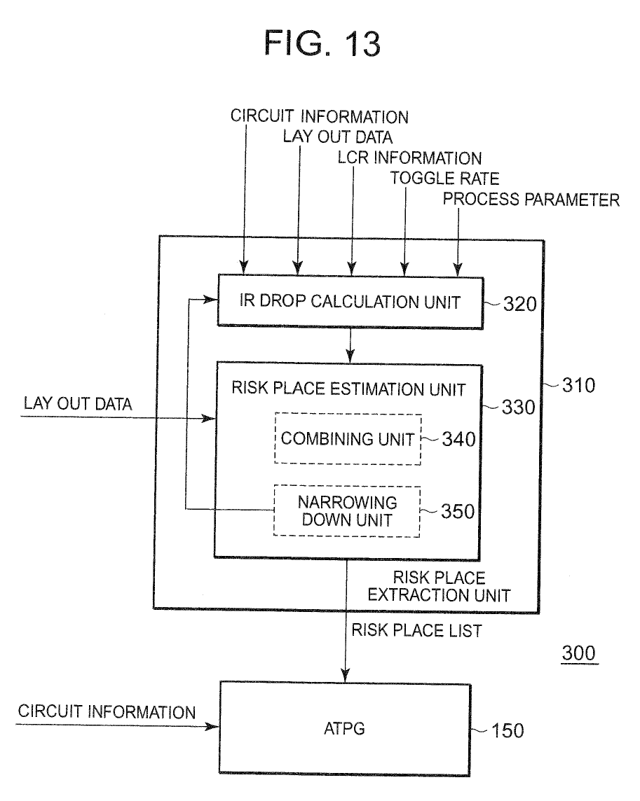

FIG. 13 shows the test pattern generation device 300 according to the third embodiment of the present invention. The test pattern generation device 300 is also designed to generate test patterns for scan testing chips, and includes a risk place extraction unit 310 for extracting risk places where errors in LSI operation may occur during test due to an IR drop in the power source and the ATPG150 for generating test patters in such a way that a constraint may be applied to the toggle rate of instances included in the risk places extracted by the risk place extraction unit 310. Here, we assign the same code in FIG. 13 to the units having the similar configuration and function as those of the test pattern generation device 100 according to the first embodiment shown in FIG. 1, and we omit detailed descriptions thereof.

The risk place extraction unit 310 includes an IR drop calculation unit 320 and a risk place estimation unit 330, and the risk place estimation unit 330 includes further a combination unit 340 and a narrowing down unit 350.

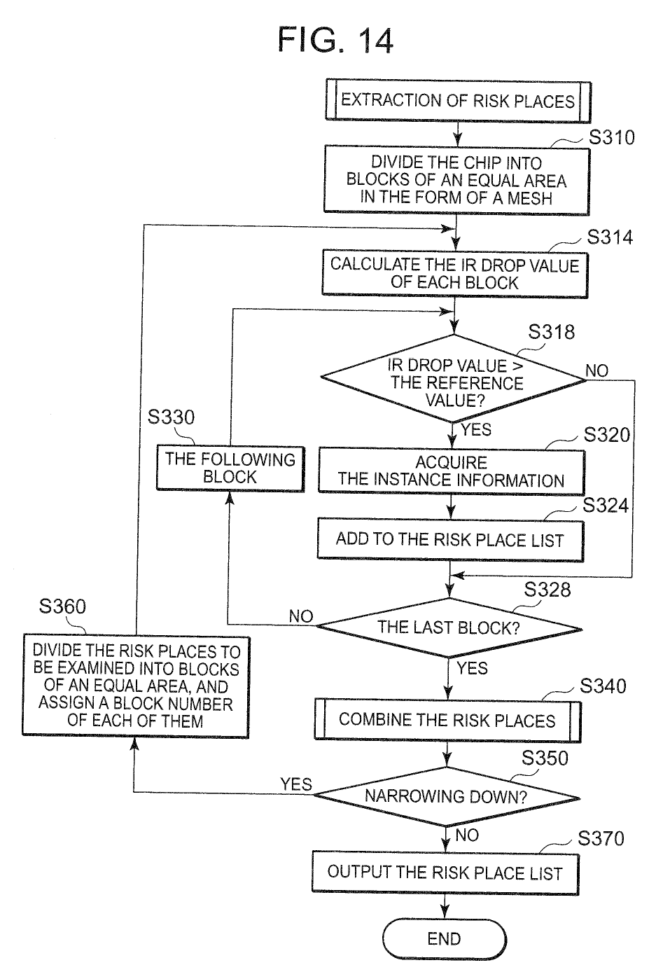

We will describe the operations of the risk place extraction unit 310 with reference to the flowchart shown in FIG. 14. As FIG. 14 shows, for extracting risk places, in the first place the risk place extraction unit 310 divides the chip into a plurality of blocks of equal area in a mesh and calculates the IR drop value of each block (S310, S314). The risk place estimation unit 330 compares the IR drop value obtained by the IR drop value calculation unit 320 and the reference value, determines the blocks whose IR drop value is larger than the reference value as risk places, refers the layout data, acquires the instance information in the block, and adds the same to the risk place list (S318: Yes, S324). On the other hand, it determines the blocks whose IR drop value is equal to or smaller than the reference value as not risk places (S318: No). The risk place estimation unit 330 executes the process beginning with the step S318 and ending with the step S324 on each block of the chip (S328: No. S330, S318-S324). When the processing of the last block is completed (S28: Yes), the combination unit 340 performs the combination processing of blocks (S340). The combination processing of the step S340 is performed by the combination unit 340. The combination unit 340 refers the risk place list and the layout data obtained by the processing that has been carried out so far, and, if there are neighboring blocks determined as risk places, combines them into a single block, renews the risk place list and output the same to the narrowing down unit 350. If, on the contrary, there are no neighboring blocks determined as risk places, it outputs the risk place list to the narrowing down unit 350 as the latter stands.

Incidentally, the processing described so far is the same as the processing carried out by the risk place estimation unit 230 in the test pattern generation device 200 shown in FIG. 8 except that the combination unit 340 outputs the risk place list to the narrowing down unit 350.

The narrowing down unit 350, in the first place, refers the risk place list outputted by the combination unit 340 and determines whether it will proceed to a narrowing down or not. We will describe further below the details of the narrowing down operation. However, in this embodiment the narrowing down unit 350 determines whether it will proceed to a narrowing down processing or not based on whether the following two requirements are satisfied or not.

1. The dimensions of the block are equal to or smaller than the predetermined threshold value M.
2. The number of instances in the block is equal to or smaller than the predetermined threshold value N (N: a natural number equal to 1 or more).

The narrowing down unit 350 determines that it will not proceed to a narrowing down operation if any one of the two requirements mentioned above is satisfied. On the other hand, if none of the requirements mentioned above is satisfied, it determines that it will proceed to a narrowing down processing. Incidentally, the threshold values M and N are variable depending on the dimensions and the construction of the chip.

If there are no blocks determined to be the subject of a narrowing down processing among the blocks included in the risk place list outputted by the combination unit 340, the narrowing down unit 350 outputs the risk place list outputted by the combination unit 340 to the ATPG150 as it is (S350: No, S370). On the other hand, if there are blocks determined to be the subject of a narrowing down processing, it specifies the blocks as the subject risk places, divides them further into smaller blocks of equal dimensions, and assigns new block numbers to the plurality of blocks newly acquired (S350: Yes, S360). And its processing returns to the step S314 and makes the processing beginning with the step S314 carried out on these small blocks (S3140-).

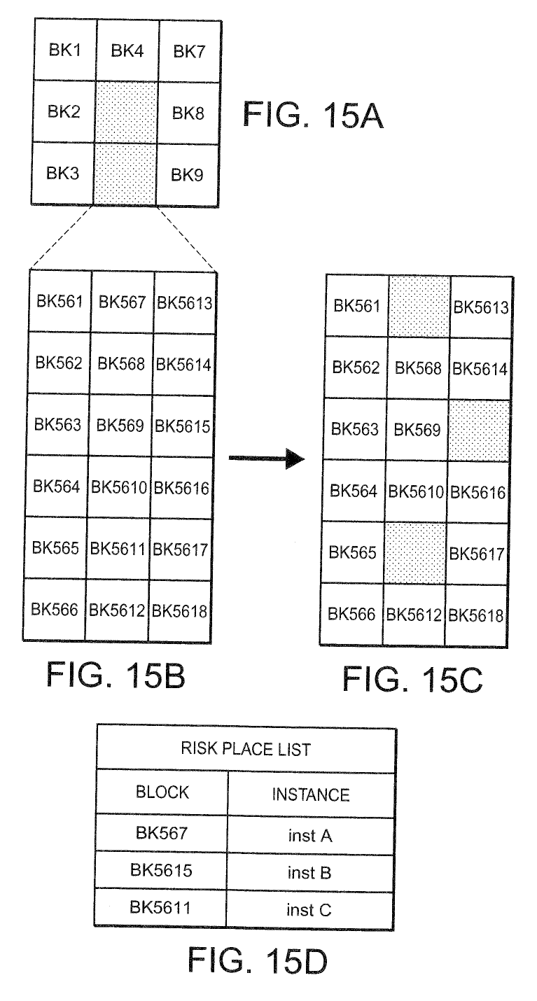

FIGS. 15A, 15B, 15C, and 15D show the processing of the risk place extraction unit 310 with specific examples. To begin with, the chip is divided into nine blocks (BK1-BK9) by the division of block by the IR drop value calculation unit 320 and the estimation of risk places by the risk place estimation unit 330, the blocks to be determined as risk places are extracted, and the risk place list is prepared. As FIG. 15A shows, the blocks BK5 and BK6 are extracted as risk places here.

Based on this risk place list and the layout data, and if there are neighboring risk places, the combination unit 340 combines these risk places into a block and renews the risk place list. On the other hand, if there are no neighboring risk places, it outputs the risk place list to the narrowing down unit 350 as the latter stands. In the example shown in FIG. 15A, since the block BK5 and the block BK 6 considered to be risk places are neighboring, the combination unit 340 combines BK5 and BK6 into a single block (for example BK56), renews the risk place list and outputs the same to the narrowing down unit 350.

The narrowing down unit 350 performs a narrowing down processing on the blocks it had determined as the subject of narrowing down processing among the blocks included in the risk place list outputted by the combination unit 340. As FIG. 15B show, the narrowing down unit 350 divides further the BK56 obtained by the combination by the combination unit 340 into a plurality of small blocks (BK561-BK5618) of equal dimensions.

And as a result of the calculation of the IR drop value in the BK561-BK 5618 by the IR drop calculation unit 320 and the comparison of the IR drop value with the reference value, as shown in FIG. 15C, the blocks BK567, BK5611, and BK5615 are extracted as risk places, and incidentally the risk place list is also renewed.

Now, since the blocks BK567, BK5611, and BK5615 are not neighboring blocks, they are not combined by the combination unit 340. And here let's suppose that a determination has been made that no narrowing down processing will be performed on the blocks BK567, BK5611 and BK5615. In this case, the risk place list shown in FIG. 15D will be outputted to the ATPG150.

Here, we omit the description of the processing of the ATPG150.

Thus, by using the test pattern generation device 300 of this embodiment, it is possible to obtain the same effect as the test pattern generation device 100 and the test pattern generation device 200, and by performing a narrowing down processing, it is possible to reduce the number of objects for which a constraint must be applied to the toggle rate and to reduce the time required to generate test patterns by the ATPG150. In addition, it is also possible to reduce the pattern length of the test patterns to be generated and to prevent their detection rate from falling down.

### Fourth Embodiment

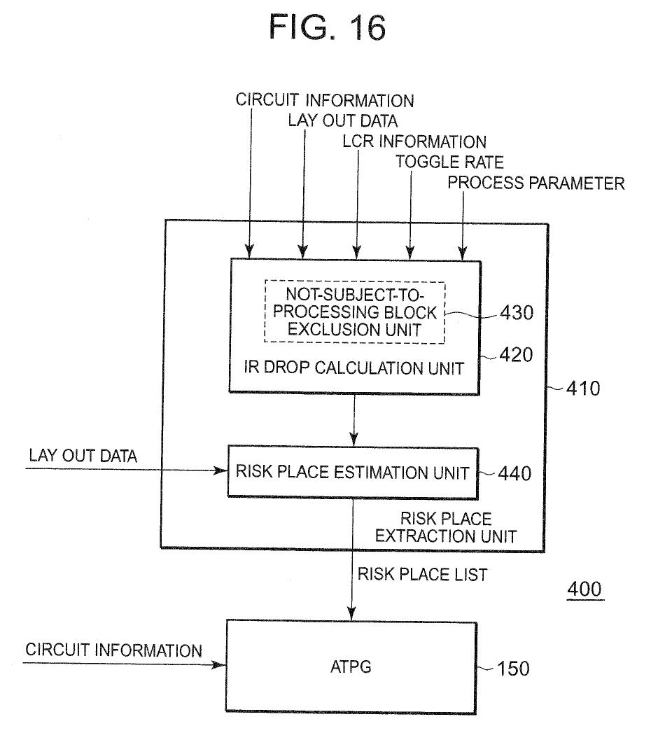

FIG. 16 shows the test pattern generation device 400 according to the fourth embodiment of the present invention. The test pattern generation device 400 is also designed to generate test patterns for scan testing chips, and includes a risk place extraction unit 410 for extracting risk places in which errors in LSI operation may occur during a test due to an IR drop in the power source, and the ATPG150 for generating test patterns in such a way that a constraint may be applied to the toggle rate of instances included in the risk places extracted by the risk place extraction unit 110. Here, we assign the same code in FIG. 16 to the units having the similar configuration and function as those of the test pattern generation device 100 according to the first embodiment shown in FIG. 1, and we omit detailed descriptions thereof.

The risk place extraction unit 410 includes an IR drop calculation unit 420 and a risk place estimation unit 440.

The IR drop calculation unit 420 is different from the IR drop calculation unit in the test pattern generation device according to various embodiments described above only in that it includes a non-subject block exclusion unit 430. The non-subject block exclusion unit 430 is designed to exclude blocks having a low possibility of errors occurring in LSI operation under the impact of an IR drop from among a plurality of blocks obtained by dividing a chip into a mesh with equal area from the subject of calculation of IR drop value. Specifically, the non-subject block exclusion unit 430 investigates the number of scan flip-flops (FF) included in each block by referring the circuit information and layout data and analyzing the circuit configuration. And it compares the number of FF included therein with the predetermined threshold value of 1 or more, and excludes the blocks having a number of FF equal to or less than the threshold value from the subject of calculation of IR drop values as blocks having a low possibility of making errors in LSI operation, in other words the subject of risk place extraction. Incidentally, this threshold value is also variable depending on the scale and construction of the chip.

And the IR drop calculation unit 420 calculates the IR drop value only for the blocks that are not excluded by the non-subject block exclusion unit 430 and outputs the result to the risk place estimation unit 440.

The risk place estimation unit 440 estimates risk places from the blocks from which IR drop values have been outputted by the IR drop calculation unit 420. The risk place estimation unit 440 may be any one of the risk place estimation units in the test pattern generation device of the embodiments mentioned above, and we omit the description thereof here.

Thus, according to the test pattern generation device 400 of this embodiment, it is possible to reduce the calculating time of the IR drop value by taking note of the fact that the importance of possibility of errors occurring in the LSI operation under the impact of IR drop is related with the number of FF and by excluding the blocks having a limited number of FF from the calculation of IR drop values, in other words from the subject blocks of extracting risk places. In particular, in the case where a configuration like that of the test pattern generation device 300 having a narrowing down mechanism is adopted, the narrowing down operations may be carried out several times and the effect of reducing TAT is remarkable.

### Fifth Embodiment

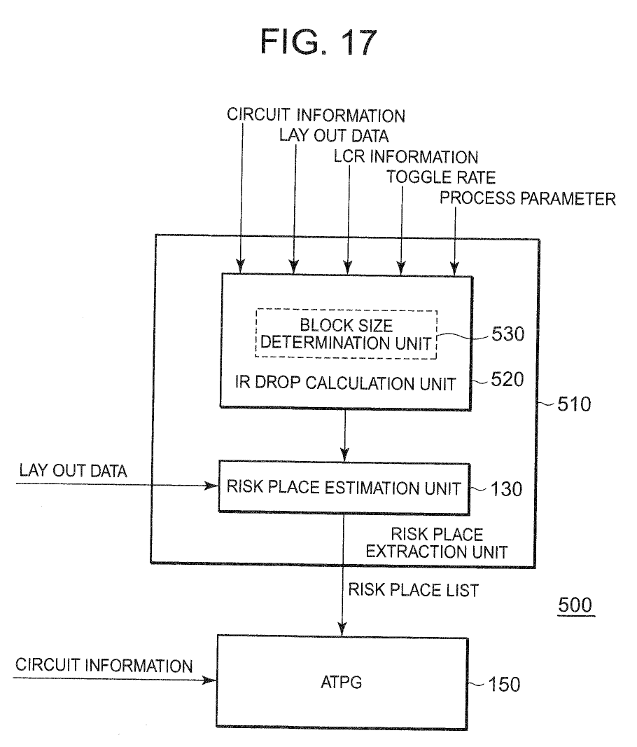

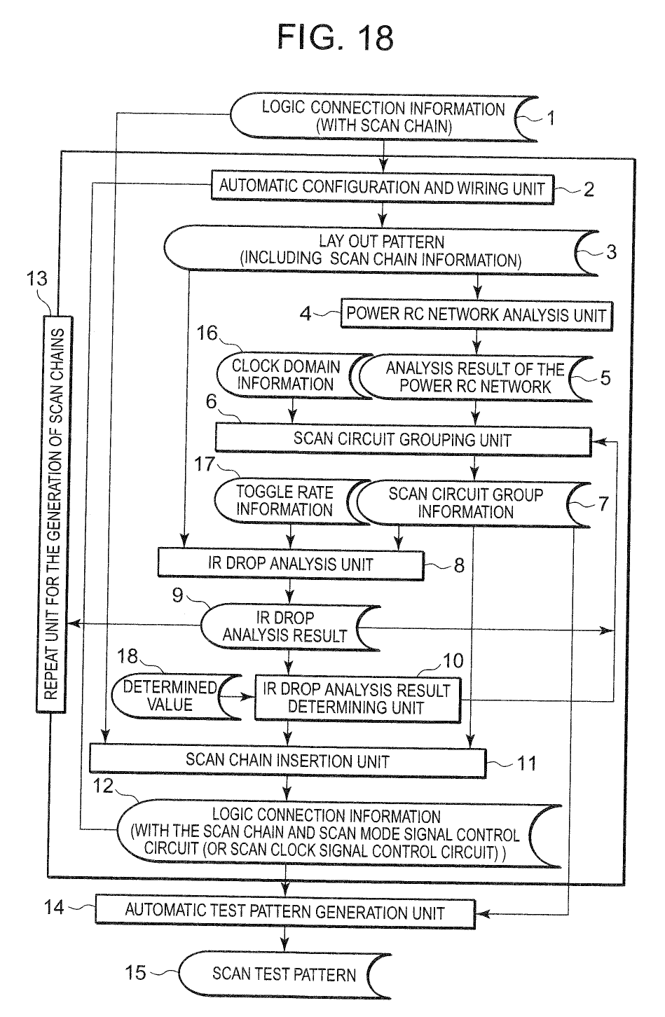

FIG. 17 shows the test pattern generation device 500 according to the fifth embodiment of the present invention. The test pattern generation device 500 is also designed to generate test patterns for scan testing chips, and includes a risk place extraction unit 510 for extracting risk places in which errors in LSI operation may occur during a test due to an IR drop in the power source from the chip, and the ATPG150 for generating test patterns in such a way that a constraint may be applied to the toggle rate of instances included in the risk places extracted by the risk place extraction unit 510. Here, we assign the same code in FIG. 17 to the units having the similar configuration and function as those of the test pattern generation device 100 according to the first embodiment shown in FIG. 1, and we omit detailed descriptions thereof.

The risk place extraction unit 510 includes an IR drop calculation unit 520 and a risk place estimation unit 130.

The IR drop calculation unit 520 is different from the IR drop calculation unit in the test pattern generation device according to various embodiments described above only in that it includes a block size determination unit 530.

The block size determination unit 530 determines the block size by referring the layout data so that the higher the degree of integration is, the smaller may become the size of a block of the position, depending on the degree of integration of the circuit. And the IR drop calculation unit 420 divides a chip into a plurality of blocks according to the block size determined by the book size determination unit 530 and calculates the IR drop value of each block. Based on the IR drop value of each block obtained from the IR drop calculation unit 420, the risk place estimation unit 130 estimates risk places, obtains a risk place list and offers the same for the generation of test patterns by the ATPG 150. We omit here the detailed description of the processing by the risk place estimation unit 130 and the ATPLG 150.

Thus, the test pattern generation device 500 according to this embodiment calculates IR drop values by dividing a chip in such a way that the higher the degree of integration at the position is, the smaller the block size may become, and the lower the degree of integration at the position is, the larger the block size may become. Thus, it is possible to avoid with certainty errors in LSI operation under the impact of a IR drop, and to curtail the time required to calculate the IR drop values. And as a result, it is possible to obtain the same effect as that of the test pattern generation device 100 and the like and to curtail further the TAT.

We have so far described the present invention based on various embodiments. The embodiments are provided as examples, and various changes, increases or decreases, or combinations may be adopted to each of the examples described above provided that they do not deviate from the main purport of the invention. Persons skilled in the art understand that variations incorporating these changes, increases or decreases, or combinations are within the scope of the present invention.

What is claimed is:

1. An apparatus for LSI test comprising:
a risk place extraction unit supplied with a design information of the LSI to specify a place by estimating an error in LSI operation based on the design information of the LSI to write the place on a risk place list; and
a pattern generator unit coupled to the risk extraction unit to generate a test pattern responsive to the risk place list.

2. The apparatus for LSI test according to claim 2,
wherein the pattern generator unit further receives the design information and generates the test pattern responsive to the design information.

3. The apparatus for LSI test according to claim 1,
wherein the pattern generator unit generates the test pattern with an operation of the LSI being controlled to be lower than a predetermined threshold to prevent the error in LSI operation from occurring.

4. The apparatus for LSI test according to claim 1,
wherein the risk place extraction unit represents the risk place list in instance which is an unit of LSI logic gate.

5. The apparatus for LSI test according to claim 4,
wherein the pattern generator unit generates the test pattern with an operation of a pair of the instances being controlled to be unsimultaneously toggled by applying the test pattern.

6. The apparatus for LSI test according to claim 4, wherein the risk place extraction unit comprises:
an IR drop calculation unit calculating an value of IR drop based on the result of LSI design; and
a risk place estimation unit estimating the error in LSI operation based on the value of IR drop to specify the place.

7. The apparatus for LSI test according to claim 6,
wherein the risk place estimation unit recognizes the error in LSI operation in a case that the value of IR drop is more than a predetermined value.

8. The apparatus for LSI test according to claim 6,
wherein the IR drop calculation unit represents the value of IR drop in block which is an unit of LSI layout region.

9. The apparatus for LSI test according to claim 8,
wherein a risk place estimation unit combines a pair of the blocks neighboring each other into a new one.

10. The apparatus for LSI test according to claim 9,
wherein a risk place estimation unit divides the block into a plurality of the blocks as new ones.

11. The apparatus for LSI test according to claim 10,
wherein the IR drop calculation unit divides a LSI layout into a plurality of the blocks with equal area.

12. The apparatus for LSI test according to claim 10,
wherein the IR drop calculation unit divides a LSI layout into a plurality of the blocks in reverse relationship between area of LSI layout and density of LSI circuitry.

13. The apparatus for LSI test according to claim 10,
wherein the IR drop calculation unit divides a LSI layout into a plurality of the blocks in reverse relationship between area of LSI layout and density of LSI circuitry.

14. The apparatus for LSI test according to claim 10,
wherein the IR drop calculation unit operates in a case that a number of scan-flipflop inside the block is more than a predetermined number and
the pattern generator unit generates the test pattern for LSI scan-test.

15. A method for LSI test comprising:
specifying a place by estimating an error in LSI operation based on a design information of the LSI;
writing the place on a risk place list;
associating the risk place list with a constraint; and
generating a test pattern by applying the constraint to an automatic test pattern generation tool.

16. The method for LSI test according to claim 15,
wherein associating the risk place list with the constraint includes asserting a toggle rate, which of the test pattern prevents the error in LSI operation from occurring, into the constraint.

17. The method according to claim 15,
wherein writing the place on the risk place list includes representing the risk place list in instance which is an unit of LSI logic gate.

18. The method for LSI test according to claim 17,
wherein associating the risk place list with the constraint includes asserting a pair of the instances, which are unsimultaneously toggled by applying the test pattern, in the constraint.

19. The method for LSI test according to claim 17,
wherein estimating an error in LSI operation based on a design information of the LSI comprises:
calculating an value of IR drop based on the design information of the LSI; and
estimating the error in LSI operation based on the value of IR drop to specify the place.

20. The method for LSI test according to claim 19,
wherein estimating the error in LSI operation based on the value of IR drop includes recognizing the error in LSI operation in a case that the value of IR drop is more than a predetermined value.
